(19) United States
(12) Patent Application Publication
(10) Pub. No.: US 2026/0310268 A1
(43) Pub. Date: Oct. 8, 2026

(54) Mount System for an Information Handling System Having an Integrated Air Flow Component

(71) Applicant: Dell Products L.P., Round Rock, TX (US)

(72) Inventors: David L. Roper, Austin, TX (US); Emily Clark, Round Rock, TX (US); Megan Wingfield, Dalzell, SC (US)

(21) Appl. No.: 19/171,283

(22) Filed: Apr. 6, 2025

(51) Int. Cl. G06F 1/18; G06F 1/20; H05K 7/20

(52) U.S. Cl. CPC G06F 1/185; G06F 1/20; H05K 7/20145

(57) ABSTRACT

A system and method for providing an information handling system with a mount system having an integrated thermal component. The mount system includes a plurality of connector receptacles, each of the plurality of connector receptacles being configured to receive a respective memory module, the plurality of connector receptacles being positioned to arrange the respective memory modules in an array; and, an integrated thermal component, the integrated thermal component being mechanically attached to a connector receptacle of the plurality of connector receptacles, the integrated thermal component being positioned to avoid touching the memory module when the memory module installed in the connector receptacle.

### BACKGROUND OF THE INVENTION

### Field of the Invention

The present invention relates to information handling systems. More specifically, embodiments of the invention relate to memory connectors used within information handling systems.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY OF THE INVENTION

A system and method are disclosed for providing an information handling system with a mount system having an integrated air flow component.

More specifically, in one embodiment the invention relates to a memory system for an information handling system, comprising: a connector receptacle, the connector receptacle being configured to receive a memory module; and, an integrated thermal component mechanically attached to the connector receptacle, the integrated thermal component being positioned to avoid touching the memory module when the memory module installed in the connector receptacle.

In another embodiment the invention relates to a mount system comprising: a plurality of connector receptacles, each of the plurality of connector receptacles being configured to receive a respective memory module, the plurality of connector receptacles being positioned to arrange the respective memory modules in an array; and, an integrated thermal component, the integrated thermal component being mechanically attached to a connector receptacle of the plurality of connector receptacles, the integrated thermal component being positioned to avoid touching the memory module when the memory module installed in the connector receptacle.

In another embodiment the invention relates to a system comprising: a processor; a data bus coupled to the processor; and a mount system coupled to the processor via the data bus, the mount system comprising: a plurality of connector receptacles, each of the plurality of connector receptacles being configured to receive a respective memory module, the plurality of connector receptacles being positioned to arrange the respective memory modules in an array; and, an integrated thermal component, the integrated thermal component being mechanically attached to a connector receptacle of the plurality of connector receptacles, the integrated thermal component being positioned to avoid touching the memory module when the memory module installed in the connector receptacle.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a mount system configured with a plurality of connector receptacles.

FIGS. 3A, 3B and 3C, generally referred to as FIG. 3, show views of portions of a mount system having a plurality of connector receptacles.

FIGS. 4A and 4B, generally referred to as FIG. 4, show views of connector receptacle and memory module of a mount system.

FIG. 5 shows a side view of a mount system configured with a plurality of connector receptacles.

### DETAILED DESCRIPTION

A system and method are disclosed for providing an information handling system with memory connectors having an integrated air flow geometry component.

Various aspects of the disclosure reflect an appreciation that implementing an air flow geometry component between memory modules improves the thermal performance of the memory modules. Various aspects of the present disclosure include an appreciation that it is known to implement air flow geometry components with a spiraling geometry. Various aspects of the present disclosure include an appreciation that known to air flow geometry components are often implemented to be connected directly to a memory module or to be positioned between pairs of memory modules, sometimes via a twisted tape type component.

A system and method are disclosed for providing a memory module slot with an integrated thermal component. In certain embodiments, the integrated thermal component is integrated into a connector receptacle of a mount system. In certain embodiments, such an integrated thermal component expands a thermal component implementation to include a thermal component implementation which can be provided via a connector vendor.

In certain embodiments, the thermal component includes an integrated air flow geometry. In certain embodiments, the air flow geometry includes a spiraling air flow geometry. In certain embodiments, the thermal component is structurally included with a connector receptacle rather than being connected directly to the memory module.

In certain embodiments, the thermal component is provided to be attached by a consumer to the connector body itself. In certain embodiments, the thermal component is molded or attached to the body of the connector receptacle. In certain embodiments, the thermal component may be offered as a thermal high-performance connector product by a component vendor.

In various embodiments, the thermal component is molded into, attached to, or attachable to a single connector body. In certain embodiments, the thermal component can be offered as a thermal high-performance connector product from a component vendor. In certain embodiments, the thermal component can be attached before or after the memory modules are installed. Providing such an attachment option facilitates future upgraded air flow components, an easy ability to accommodate memory module pitch variations and allows repairability in the field or factory.

In various embodiments, the thermal component can be implemented on either or both sides of the connector receptacle. In various embodiments, thermal component configuration provides an ability to add double sided cooling to memory locations that previously could not have had coverage on both sides of the memory components.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

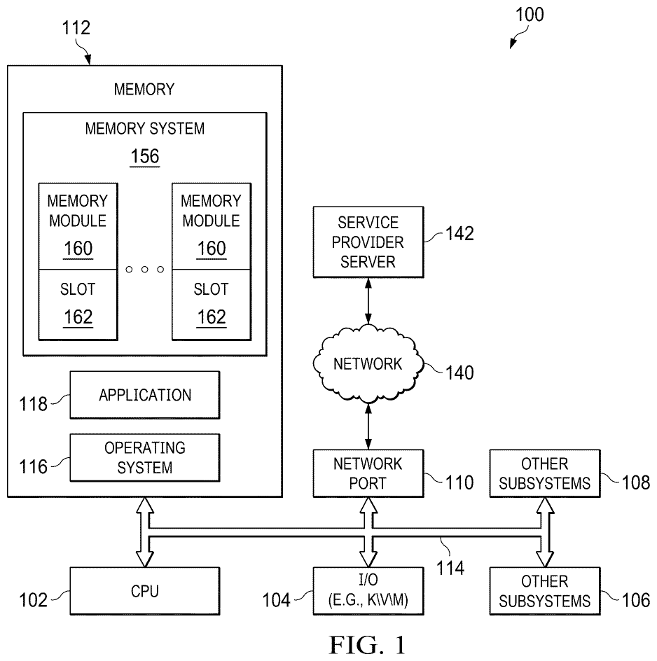

FIG. 1 is a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, a touchpad or touchscreen, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116 and in various embodiments may also comprise an application 118. In one embodiment, the information handling system 100 is able to download the application 118 from the service provider server 142. In another embodiment, the application 118 is provided as a service from the service provider server 142.

In various embodiments, the system memory 112 includes a memory system 150 coupled to processor 102. In various embodiments, the memory system 150 may include RAM, EEPROM, a PCMCIA card, flash memory, magnetic storage, opto-magnetic storage, or any suitable selection and/or array of volatile or non-volatile memory. In various embodiments, some or all of the components of the memory system 150 retain data after power to information handling system 102 is removed.

In certain embodiments, the memory system 150 includes a plurality of memory slots 162, each configured to receive a corresponding memory module 160. A memory slot 162 may include any system, device, or apparatus configured to receive a memory module 160 to physically, electrically, or a combination thereof, the memory module 160 to the processor 102. Each memory module 160 includes a system, device or apparatus configured to retain program instructions and/or data (e.g., computer-readable media). In certain embodiments, each memory module 160 includes one or more of a dynamic random access memory (DRAM) module (e.g., a dual in-line package (DIP) memory, a Single In-line Pin Package (SIPP) memory, a Single-Inline Memory Module (SIMM), a Dual-Inline Memory Module (DIMM), a Ball Grid Array (BGA)), or any other suitable memory.

In certain embodiments, one or more memory module slots are configured with an integrated thermal component. In certain embodiments, the integrated thermal component is integrated into a connector receptacle of a mount system. In certain embodiments, such an integrated thermal component expands a thermal component implementation to include a thermal component implementation which can be provided via a connector vendor.

In certain embodiments, the thermal component includes an integrated air flow geometry. In certain embodiments, the air flow geometry includes a spiraling air flow geometry. In certain embodiments, the thermal component is structurally included with a connector receptacle rather than being connected directly to the memory module.

In certain embodiments, the thermal component is provided to be attached by a consumer to the connector body itself. In certain embodiments, the thermal component is molded or attached to the body of the connector receptacle. In certain embodiments, the thermal component may be offered as a thermal high-performance connector product by a component vendor.

In various embodiments, the thermal component is molded into, attached to, or attachable to a single connector body. In certain embodiments, the thermal component can be offered as a thermal high-performance connector product from a component vendor. In certain embodiments, the thermal component can be attached before or after the memory modules are installed. Providing such an attachment option facilitates future upgraded air flow components, an easy ability to accommodate memory module pitch variations and allows repairability in the field or factory.

In various embodiments, the thermal component can be implemented on either or both sides of the connector receptacle. In various embodiments, thermal component configuration provides an ability to add double sided cooling to memory locations that previously could not have had coverage on both sides of the memory components.

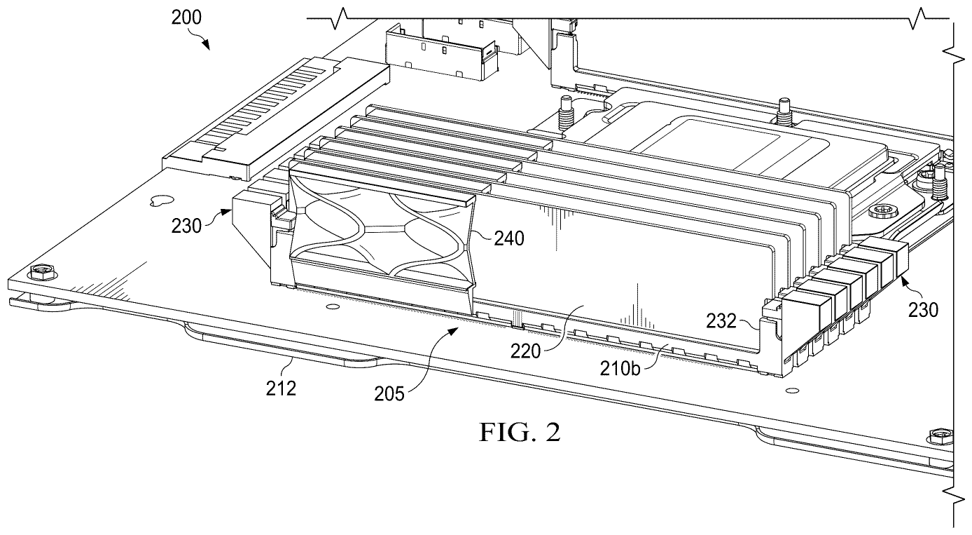

FIG. 2 shows a perspective view of a portion of an information handling system 200 having a mount system 230. In certain embodiments, the mount system 200 includes a plurality of connector receptacles 210. In certain embodiments, the mount system 230 is included within a memory system such as memory system 150.

In certain embodiments, the connector receptacles 210 are mechanically coupled to a circuit board 212 of the information handling system. In certain embodiments, the connector receptacles 210 are configured to receive corresponding memory modules 220. In certain embodiments, a memory module 220 includes a corresponding DIMM. In certain embodiments, each memory module 220 corresponds to a memory module 160. In certain embodiments, each connector receptacle 210 corresponds to a slot 162. In certain embodiments, only some of the connector receptacles 210 of the mount system 200 have corresponding memory modules 220 mounted therein. Other connector receptacles 220 may have blank components mounted therein or may be empty.

In certain embodiments, the connector receptacles 210 are positioned such that corresponding memory modules 220 are arranged in an array. In certain embodiments, each connector receptacle 210 includes a first side connector receptacle and a second side connector receptacle 210b. In certain embodiments, each connector receptacle 210 includes one or more latching mechanisms 230. In certain embodiments, the latching mechanisms 230 are located on one edge of the connector receptacle 210 or on both ends of the connector receptacle 210. In certain embodiments, each connector receptacle 210 includes one or more guide elements 232. In certain embodiments, the guide elements 232 are located on one edge of the connector receptacle 210 or on both ends of the connector receptacle 210. In certain embodiments, the guide elements 232 are positioned such that a contact portion of a memory module 220 is guided to couple with a connector receptacle 210 as the memory module 220 is inserted into the connector receptacle 210.

In some embodiments, the connector receptacles 210 are positioned to allow a mechanical accessory (e.g., thermal component 240) to be positioned between pairs of memory modules 220. For example, as shown in FIG. 2, a thermal component 240 may be positioned between a pair of memory modules 220 to improve cooling of the memory modules 220. In certain embodiments, a thermal component 240 may be integrated with a respective connector receptacle 210. For illustration purposes, the thermal component 240 is shown in an orientation before the thermal component 240 is attached to a portion of a connector receptacle 210.

While FIG. 2 shows a thermal component 240 extending across a portion of a memory module 220, one of ordinary skill in the art would understand the thermal inserts 240 may extend across any or all of the corresponding memory module 220. Accordingly, the connector receptacles 210 may be positioned to align and constrain a thermal component 240 during installation and normal use of the memory modules such that thermal component 240 may avoid touching and/or damaging adjacent memory modules 220.

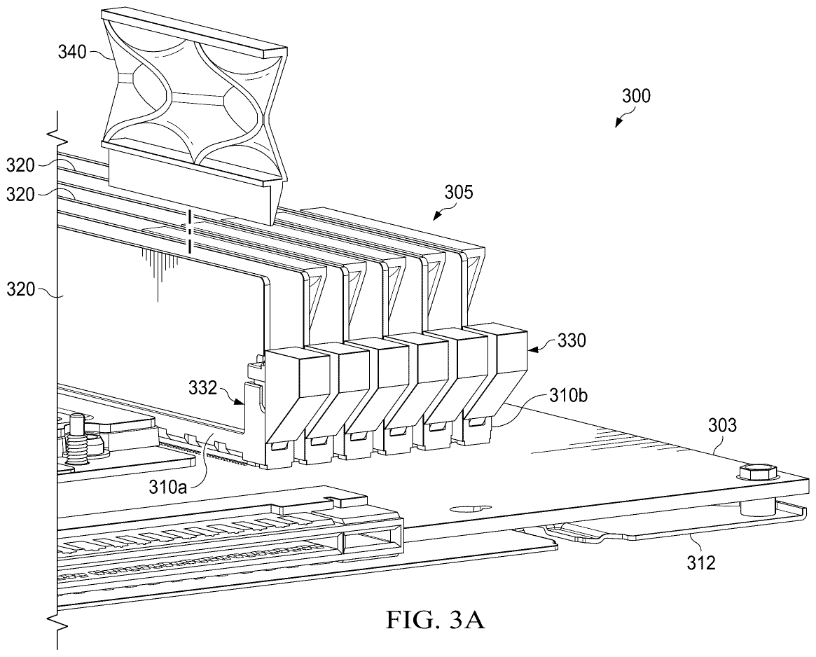

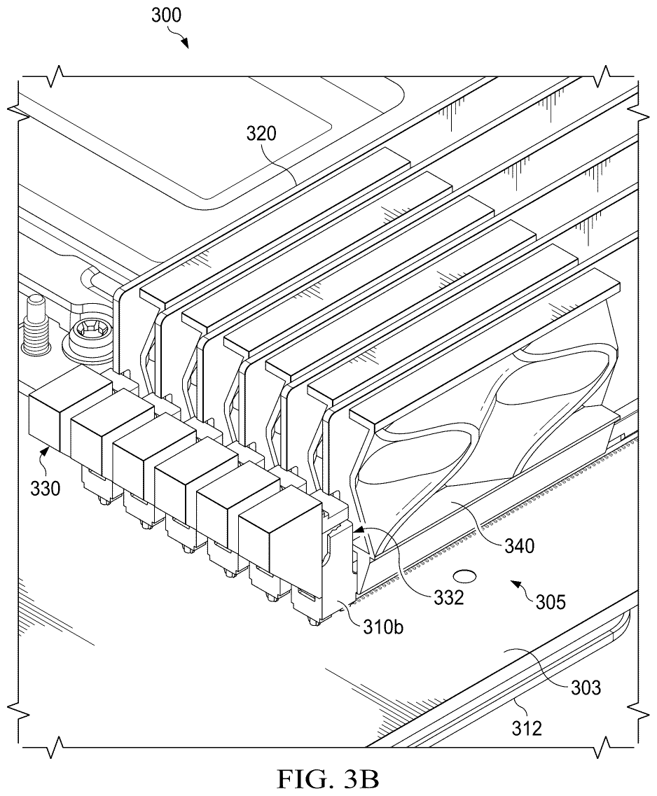

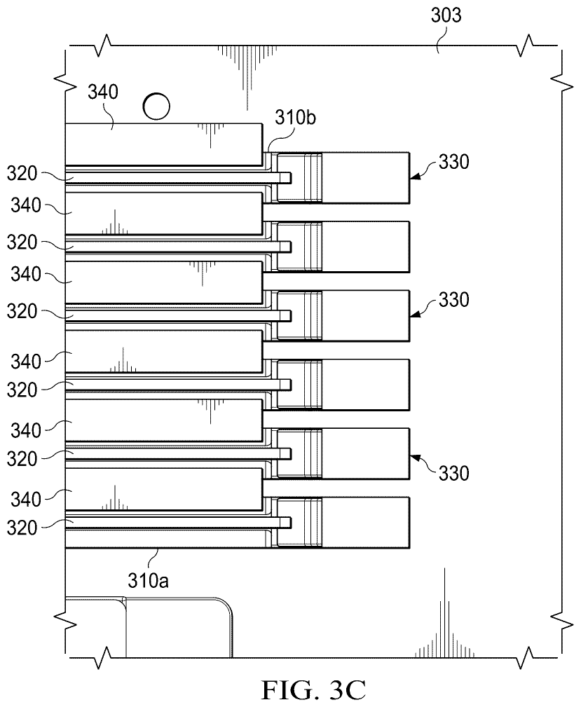

FIGS. 3A, 3B and 3C, generally referred to as FIG. 3, show views of portions of a mount system 300 having a plurality of connector receptacles. More specifically, FIG. 3A shows a front perspective view of a portion of a mount system having a plurality of connector receptacles. FIG. 3B shows a rear perspective view of a portion of a mount system 300 having a plurality of connector receptacles. FIG. 3C shows a top view of a portion of a mount system 300 having a plurality of connector receptacles. In certain embodiments, the mount system 300 is included within a memory system such as memory system 150.

In certain embodiments, the connector receptacles 310 are mechanically coupled to a circuit board 312 of the information handling system. In certain embodiments, the connector receptacles 310 are configured to receive a corresponding memory module 320. In certain embodiments, each memory module 320 includes a corresponding DIMM. In certain embodiments, each memory module 320 corresponds to a memory module 160. In certain embodiments, each connector receptacle 310 corresponds to a slot 162. In certain embodiments, only some of the connector receptacles 310 of the mount system 300 have corresponding memory modules 320 mounted therein. Other connector receptacles 310 may have blank components mounted therein or may be empty.

In certain embodiments, the connector receptacles 310 are positioned such that corresponding memory modules 320 are arranged in an array. In certain embodiments, each connector receptacle 310 includes a first side connector receptacle and a second side connector receptacle 310b. In certain embodiments, each connector receptacle 310 includes one or more latching mechanisms 330. In certain embodiments, the latching mechanisms 330 are located on one edge of the connector receptacle 310 or on both ends of the connector receptacle 310. In certain embodiments, each connector receptacle 310 includes one or more guide elements 332. In certain embodiments, the guide elements 332 are located on one edge of the connector receptacle 310 or on both ends of the connector receptacle 310. In certain embodiments, the guide elements 332 are positioned such that a contact portion of a memory module 320 is guided to couple with a connector receptacle 310 as the memory module 320 is inserted into the connector receptacle 310.

In some embodiments, the connector receptacles 310 are positioned to allow a mechanical accessory (e.g., thermal component 340) to be positioned between pairs of memory modules 320. For example, as shown in FIG. 3, a thermal component 340 may be positioned between a pair of memory modules 320 to improve cooling of the memory modules 320. In certain embodiments, a thermal component 340 may be integrated with a respective connector receptacle 310. For illustration purposes, the thermal component 340 is shown in an orientation before the thermal component 340 is attached to a portion of a connector receptacle 310.

While FIG. 3 shows a thermal component 340 extending across a portion of a memory module 320 (e.g., about half of the length of the corresponding memory module), one of ordinary skill in the art would understand the thermal inserts 340 may extend across any or all of the corresponding memory module 320. Additionally, while FIG. 3 shows a thermal component 340 positioned to modify the air flow on a latter side of the air flow across the memory module 320, one of ordinary skill in the art would understand the thermal inserts 340 could be positioned to modify the air flow anywhere across the corresponding memory module 320 (e.g., on an early side of the air flow, at a midway location of the air flow or across all of the corresponding memory module 320). Accordingly, the connector receptacles 310 may be positioned to align and constrain a thermal component 340 during installation and normal use of the memory modules such that thermal component 340 may avoid touching and/or damaging adjacent memory modules 320.

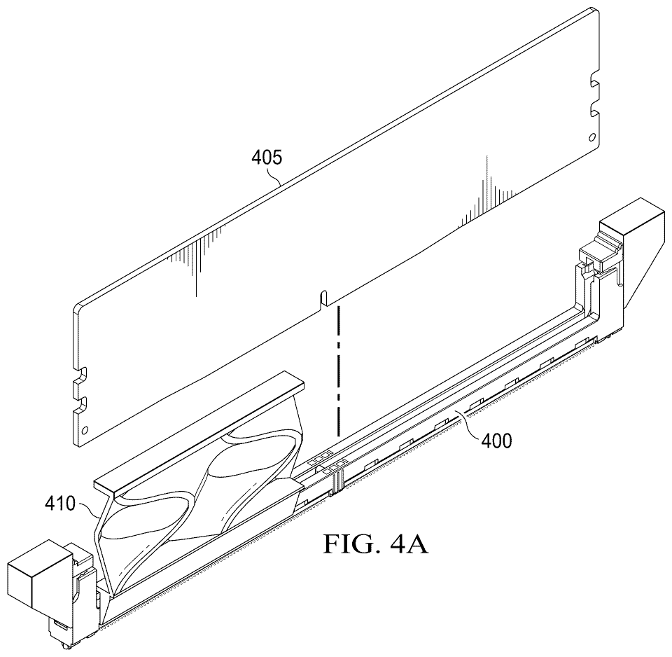

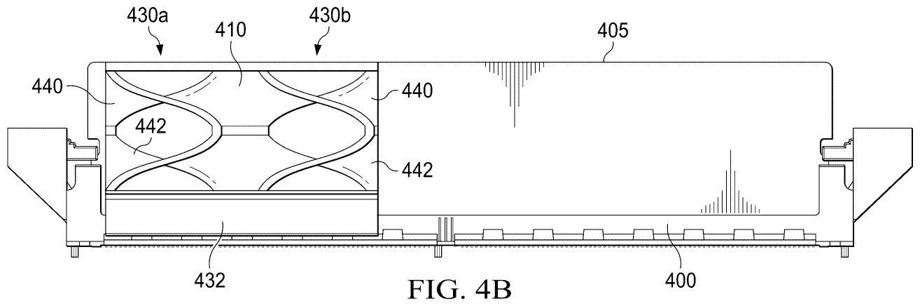

FIGS. 4A and 4B, generally referred to as FIG. 4, show views of connector receptacle 400 and memory module 405 of a mount system. In certain embodiments, the connector receptacle 400 corresponds to a slot 162. In certain embodiments, the memory module 405 corresponds to a memory module 160.

In certain embodiments, an integrated thermal component 410 is integrated with the connector receptacle 400. In certain embodiments, such an integrated thermal component 410 expands a thermal component implementation to include a thermal component implementation which can be provided via a connector vendor.

In certain embodiments, the thermal component 410 includes an integrated air flow geometry. In certain embodiments, the air flow geometry includes a spiraling air flow geometry. In certain embodiments, the thermal component 410 is structurally included with a connector receptacle rather than being connected directly to the memory module.

In certain embodiments, the thermal component 410 includes a plurality of air flow directing components 430, a connector mount portion 432, or a combination thereof. In certain embodiments, the plurality of air flow direction components 430 are configured to generate a spiraling air flow as cooling air flows across the thermal component. In certain embodiments, the connector mount portion 432 laterally extends across a bottom of the thermal component. In certain embodiments, the connector mount portion 432 extends across a bottom of the plurality of air flow directing components 430. In certain embodiments, the connector mount portion 432 mechanically attaches the thermal component to the connector receptacle 400. In certain embodiments, the connector mount portion 432 and some or all of the connector receptacle 400 are fabricated from a single piece of material.

In certain embodiments, the thermal component 400 is configured to be attached by a consumer to the connector body itself. In certain embodiments, the thermal component 400 is molded or attached to the body of the connector receptacle. In certain embodiments, the thermal component 400 may be offered as a thermal high-performance connector product by a component vendor.

In various embodiments, the thermal component 400 is molded into, attached to, or attachable to a single connector body via the connector mount portion 432. In certain embodiments, the thermal component 400 can be offered as a thermal high-performance connector product from a component vendor. In certain embodiments, the thermal component 400 can be attached before or after the memory modules are installed. Providing such an attachment option facilitates future upgraded air flow components, an easy ability to accommodate memory module pitch variations and allows repairability in the field or factory.

In certain embodiments, the thermal component 410 includes a pair of air flow directing components 430a, 430b. In certain embodiments, each air flow directing component 430 includes a top air flow direction component 440, a bottom air flow direction component 442, or a combination thereof. In certain embodiments, top air flow direction component 440 twists and slants in a first direction. In certain embodiments, the bottom air flow directing component 512 twists and slants in the opposite direction. The different directions of top air flow direction component 440 and bottom air flow directing component 442 causes different air flows through the thermal component 410. In certain embodiments, the connector mount portion 432 laterally extends across the bottom air flow direction component 442.

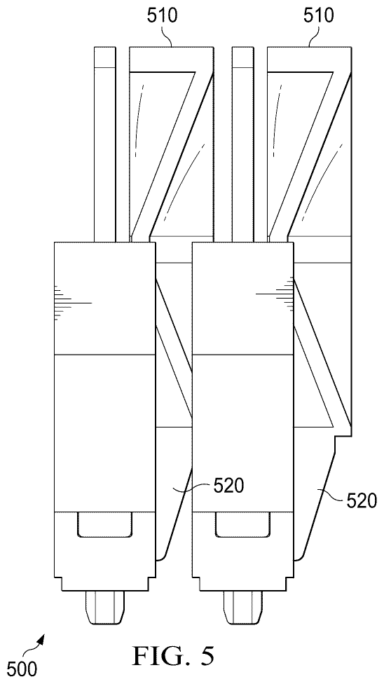

FIG. 5 shows a side view of a mount system 500 configured with a plurality of connector receptacle 505, a plurality of thermal components 510 and a plurality of memory modules 512. In certain embodiments, the connector receptacles 505 correspond to slot 162. In certain embodiments, the memory modules 512 correspond to memory modules 160.

In various embodiments, the thermal components 510 can be implemented on either or both sides of the connector receptacle 505. In various embodiments, thermal component configuration provides an ability to add double sided cooling to memory locations that previously could not have had coverage on both sides of the memory components. In certain embodiments, each thermal component 510 is mechanically attached to a respective connector receptacle 505. In certain embodiments, each thermal component 510 is mechanically attached to a respective connector receptacle 505 via receptive connector mount portions 520. In certain embodiments, each thermal component 510 is mechanically attached to a first side connector receptacle or a second side connector receptacle. In certain embodiments, each thermal component 510 is mechanically attached to a first side connector receptacle or a second side connector receptacle. connector receptacle 505 via a connector mount portion 520.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A memory system for an information handling system, comprising:
a connector receptacle, the connector receptacle being configured to receive a memory module; and,
an integrated thermal component mechanically attached to the connector receptacle, the integrated thermal component being positioned to avoid touching the memory module when the memory module installed in the connector receptacle.

2. The memory system of claim 1, wherein:
the integrated thermal component includes an air flow directing component and a connector mount portion, the connector mount portion extending laterally across the air flow directing component.

3. The memory system of claim 2, wherein:
the integrated thermal component is mechanically attached to the connector receptable via the connector mount portion.

4. The memory system of claim 2, wherein:
the integrated thermal component includes a plurality of air flow directing components; and,
the connector mount portion extends laterally across a bottom of the plurality of air flow directing components.

5. The memory system of claim 1, wherein:
the integrated thermal component is molded into, attached to, or attachable to the connector receptacle.

6. The memory system of claim 1, wherein:
the integrated thermal component is configured to be attached by a consumer to the connector receptacle.

7. A mount system comprising:
a plurality of connector receptacles, each of the plurality of connector receptacles being configured to receive a respective memory module, the plurality of connector receptacles being positioned to arrange the respective memory modules in an array; and,
an integrated thermal component, the integrated thermal component being mechanically attached to a connector receptacle of the plurality of connector receptacles, the integrated thermal component being positioned to avoid touching the memory module when the memory module installed in the connector receptacle.

8. The mount system of claim 7, wherein:
the integrated thermal component includes an air flow directing component and a connector mount portion, the connector mount portion extending laterally across the air flow directing component.

9. The mount system of claim 8, wherein:
the integrated thermal component is mechanically attached to the connector receptable via the connector mount portion.

10. The mount system of claim 8, wherein:
the integrated thermal component includes a plurality of air flow directing components; and,
the connector mount portion extends laterally across a bottom of the plurality of air flow directing components.

11. The system of claim 7, wherein:
the integrated thermal component is molded into, attached to, or attachable to the connector receptacle.

12. The system of claim 7, wherein:
the integrated thermal component is configured to be attached by a consumer to the connector receptacle.

13. A system comprising:
a processor;
a data bus coupled to the processor; and
a mount system coupled to the processor via the data bus, the mount system comprising:
a plurality of connector receptacles, each of the plurality of connector receptacles being configured to receive a respective memory module, the plurality of connector receptacles being positioned to arrange the respective memory modules in an array; and,
an integrated thermal component, the integrated thermal component being mechanically attached to a connector receptacle of the plurality of connector receptacles, the integrated thermal component being positioned to avoid touching the memory module when the memory module installed in the connector receptacle.

14. The system of claim 13, wherein:
the integrated thermal component includes an air flow directing component and a connector mount portion, the connector mount portion extending laterally across the air flow directing component.

15. The system of claim 14, wherein:
the integrated thermal component is mechanically attached to the connector receptable via the connector mount portion.

16. The system of claim 14, wherein:
the integrated thermal component includes a plurality of air flow directing components; and,
the connector mount portion extends laterally across a bottom of the plurality of air flow directing components.

17. The system of claim 13, wherein:
the integrated thermal component is molded into, attached to, or attachable to the connector receptacle.

18. The system of claim 13, wherein:
the integrated thermal component is configured to be attached by a consumer to the connector receptacle.
